(19) United States
(12) Patent Application Publication
(10) Pub. No.: US 2025/0169239 A1
(43) Pub. Date: May 22, 2025

(54) DISPLAY DEVICE AND ELECTRONIC DEVICE INCLUDING THE SAME

(71) Applicant: Samsung Display Co., LTD., Yongin-si (KR)

(72) Inventors: HANUL LEE, Yongin-si (KR); PIL GYU KANG, Yongin-si (KR); HYUN-CHUL PARK, Yongin-si (KR); YOUNGHOON YOO, Yongin-si (KR); EUNA YU, Yongin-si (KR); JEONGHYUN LEE, Yongin-si (KR); SANGCHEON HAN, Yongin-si (KR)

(21) Appl. No.: 18/946,689

(22) Filed: Nov. 13, 2024

(30) Foreign Application Priority Data
Nov. 21, 2023 (KR) 10-2023-0162764

(51) Int. Cl. H01L 33/38; H01L 25/075

(52) U.S. Cl. CPC H10H 20/831; H01L 25/0753

(57) ABSTRACT

A display device includes an active layer above a substrate, including a conductive area, and defining at least one hole, a contact electrode electrically connected to the conductive area, and having a shape that surrounds at least a portion of the hole in a plan view, and a light-emitting diode above the contact electrode, and electrically connected to the contact electrode.

### CROSS-REFERENCE TO RELATED APPLICATION

The present application claims priority to, and the benefit of, Korean Patent Application No. 10-2023-0162764, filed on Nov. 21, 2023, in the Korean Intellectual Property Office, the entire disclosure of which is incorporated herein by reference.

### BACKGROUND

### 1. Field

The present disclosure relates to a display device and electronic device including the same. More particularly, the present disclosure relates to a display device and electronic device including the same that provides visual information.

### 2. Discussion of the Related Art

Transistors are widely used as switching elements or driving elements in the electronic device field. For example, because thin film transistors may be manufactured on glass or plastic substrates, they may be widely used for switching of display devices, such as liquid crystal display devices or organic light-emitting display devices.

A transistor may drive a display device through electrical connection with a contact electrode. During the process of placing a contact electrode on a transistor, a phenomenon occurs where the transistor and the contact electrode are not electrically connected due to shift to the left or right. To solve this problem, attempts are continuing to modify the planar shape of the contact electrode.

### SUMMARY

Embodiments provide a display device with improved reliability and an electronic device including the display device.

A display device according to one or more embodiments of the present disclosure includes an active layer above a substrate, including a conductive area, and defining at least one hole, a contact electrode electrically connected to the conductive area, and having a shape that surrounds at least a portion of the hole in a plan view, and a light-emitting diode above the contact electrode, and electrically connected to the contact electrode.

The contact electrode may have a shape with one side open in plan view.

The contact electrode may include a body portion, a first protrusion protruding from the body portion in a first direction, and a second protrusion protruding from the body portion in the first direction, and spaced apart from the first protrusion in a second direction crossing the first direction.

A portion of the body portion, a portion of the first protrusion, and a portion of the second protrusion may overlap the conductive area in plan view.

The contact electrode may further include a third protrusion protruding from the first protrusion in the second direction.

At least a portion of the third protrusion may overlap the conductive area in plan view.

The contact electrode may further include a fourth protrusion protruding from the second protrusion in a direction opposite to the second direction.

At least a portion of the fourth protrusion may overlap the conductive area in plan view.

A first length of the conductive area in the second direction may be longer than a second length in which the first protrusion and the second protrusion are spaced apart along the second direction.

The conductive area may be doped with an N-type impurity.

The active layer may include a metal oxide semiconductor.

The hole may have a rectangular shape in plan view.

The hole may have a shape of a rectangle with one side protruding in plan view.

The display device may further include a light-blocking portion above the substrate, and having a portion overlapping the hole in plan view.

A display device according to one or more other embodiments of the present disclosure includes a transistor including an active layer above a substrate, including a conductive area, and defining at least one hole, and a gate electrode above the active layer overlapping a portion of the active layer, a contact electrode at a same layer as the gate electrode, electrically connected to the conductive area, and having a shape that surrounds at least a portion of the hole in a plan view, and a light-emitting diode above the contact electrode, and electrically connected to the contact electrode.

The contact electrode may have a shape with one side open in plan view.

The contact electrode may include a body portion, a first protrusion protruding from the body portion in a first direction, and a second protrusion protruding from the body portion in the first direction, and spaced apart from the first protrusion in a second direction crossing the first direction.

A portion of the body portion, a portion of the first protrusion, and a portion of the second protrusion may overlap the conductive area in plan view.

The contact electrode may further include a third protrusion protruding from the first protrusion in the second direction.

The contact electrode may further include a fourth protrusion protruding in a direction opposite to the second direction from the second protrusion.

A display device according to embodiments of the present disclosure may include an active layer located on a substrate, including a conductive area, and defining at least one hole, and a contact electrode electrically connected to the conductive area and surrounding at least a portion of the hole. In addition, the conductive electrode may include a body portion and first, second, third, and fourth protrusions protruding from the body portion.

An electronic device according to one or more embodiments of the present disclosure includes a housing and a display device stored in the housing and that displays images, the display device includes an active layer above a substrate, comprising a conductive area, and defining at least one hole, a contact electrode electrically connected to the conductive area, and having a shape that surrounds at least a portion of the hole in a plan view, and a light-emitting diode above the contact electrode, and electrically connected to the contact electrode.

Accordingly, because the contact electrode includes not only the body portion, but also the first, second, third, and fourth protrusions, the contact electrode may exchange electrical signals with the conductive area of the active layer even if the contact electrode is shifted in the left and right directions. Accordingly, the reliability of the display device may be improved.

### BRIEF DESCRIPTION OF THE DRAWINGS

The accompanying drawings, which are included to provide a further understanding of the present disclosure and are incorporated in and constitute a part of this specification, illustrate embodiments of the present disclosure together with the description.

FIG. 1 is a perspective view of a display device according to one or more embodiments of a present disclosure.

FIG. 2 is a block diagram for explaining the display device shown in FIG. 1.

FIG. 3 is a view showing an example of a pixel included in a pixel area of FIG. 2.

FIG. 4 is a plan view showing an example of a pixel in FIG. 2.

FIG. 5 is a cross-sectional view of the pixel taken along the line I-I′ of FIG. 4.

FIG. 6 is a plan view showing an enlarged example of portion A of FIG. 4.

FIG. 7 is a plan view showing another enlarged example of portion A of FIG. 4.

FIG. 8 is a plan view showing still another enlarged example of portion A of FIG. 4.

FIG. 9 is a plan view showing still another enlarged example of portion A of FIG. 4.

FIG. 10 is a plan view showing still another enlarged example of portion A of FIG. 4.

FIGS. 11, 12, 13, 14, 15, 16, and 17 are cross-sectional views showing a method of manufacturing the pixel of FIG. 5.

FIG. 18 is a block diagram showing an embodiment of an electronic device.

FIG. 19 is a perspective view showing an embodiment of the electronic device.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

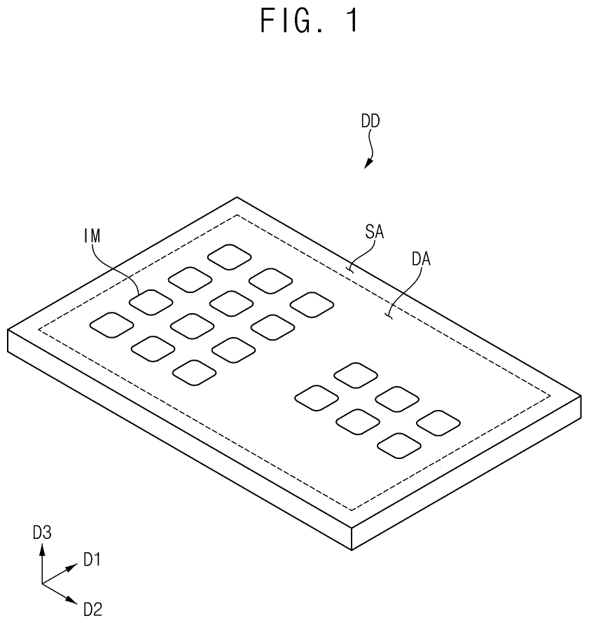

FIG. 1 is a perspective view of a display device according to one or more embodiments of a present disclosure.

Referring to FIG. 1, a display device DD may include a display area DA and a peripheral area SA. The display area DA may be surrounded by the peripheral area SA (e.g., in plan view).

The display area DA may be an area that may display an image by generating light, or by adjusting the transmittance of light provided from an external light source. The peripheral area SA may be an area that does not display an image. However, embodiments of the present disclosure are not limited thereto, and at least a portion of the peripheral area SA may display an image.

The display area DA may display a plurality of images IM. Users may receive information from the display device DD through the plurality of the images IM.

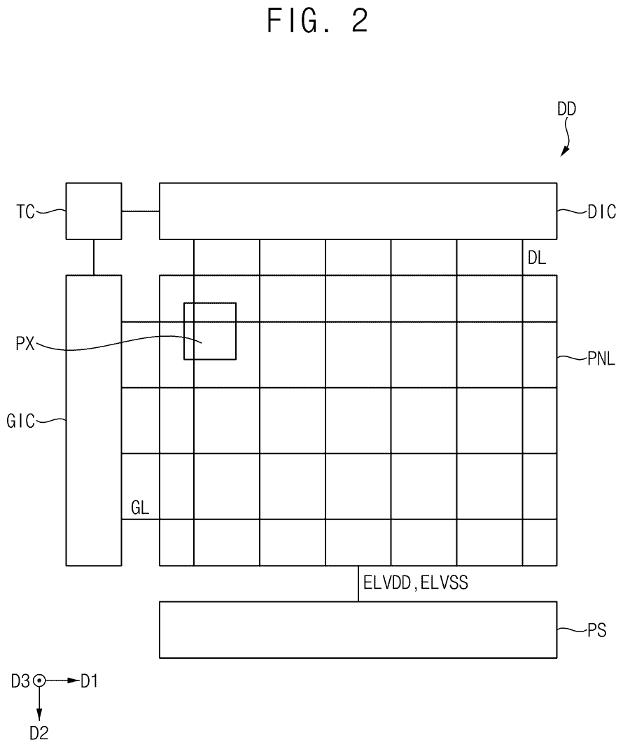

FIG. 2 is a block diagram for explaining the display device shown in FIG. 1.

Referring to FIG. 2, the display device DD may include a display panel PNL, a data driver DIC, a gate driver GIC, and a control portion TC.

A plurality of pixels PX and signal lines that may apply electrical signals to the pixels PX may be located on the display panel PNL.

The pixels PX may be repeatedly arranged in a matrix form in a plan view. For example, the pixels PX may be repeatedly arranged in the first direction D1, and in the second direction D2 that crosses the first direction D1. The signal lines may include gate lines GL extending in the first direction D1, and data lines DL extending in the second direction D2. The gate lines GL may be spaced apart along the second direction D2, and may transmit a gate signal to the pixels PX. The data lines DL may be spaced apart along the first direction D1, and may transmit data signals to the pixels PX. In one or more embodiments, each of the pixels PX may be connected to at least one corresponding gate line among the gate lines GL, and to at least one corresponding data line among the data lines DL.

The data driver DIC may be connected to the data lines DL, and may supply a data signal to the data lines DL in response to a data control signal provided from the control portion TC.

The gate driver GIC may be connected to the gate lines GL, may generate a gate signal in response to the gate control signal provided from the control portion TC, and may sequentially supply the gate signal to the gate lines GL.

The power supply portion PS may be spaced apart from the display panel PNL along the second direction D2. The power supply portion PS may transmit a driving voltage (e.g., ELVDD, ELVSS) so that the display panel PNL may be driven.

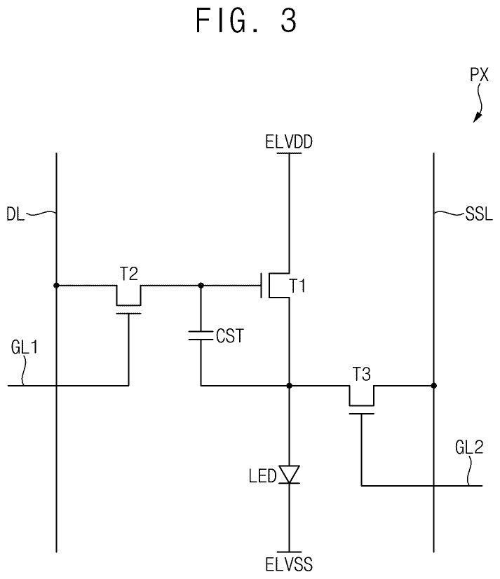

FIG. 3 is a view showing an example of a pixel included in a pixel area of FIG. 2.

Referring to FIG. 3, the pixel PX may include first, second, and third transistors T1, T2, and T3, a capacitor CST, and a light-emitting diode LED.

The first transistor T1 may include a gate electrode, a first electrode, and a second electrode. The gate electrode of the first transistor T1 may be connected to a second electrode of the capacitor CST. The first electrode of the first transistor T1 may be connected to a second electrode of the third transistor T3. A driving voltage ELVDD may be applied to the second electrode of the first transistor T1.

The second transistor T2 may include a gate electrode, a first electrode, and a second electrode. A first gate signal transmitted by the first gate line GL1 may be applied to the gate electrode of the second transistor T2. The first gate signal may be a gate-writing signal. The first electrode of the second transistor T2 may be connected to the gate electrode of the first transistor T1. The second electrode of the second transistor T2 may be connected to the data lines DL.

The third transistor T3 may include a gate electrode, a first electrode, and a second electrode. A second gate signal transmitted by the second gate line GL2 may be applied to the gate electrode of the third transistor T3. A sensing line SSL may be connected to the first electrode of the third transistor T3. The second electrode of the third transistor T3 may be connected to the first electrode of the first transistor T1.

The capacitor CST may include a first electrode and the second electrode. The first electrode of the capacitor CST may be connected to the second electrode of the third transistor T3. The second electrode of the capacitor CST may be connected to the gate electrode of the first transistor T1.

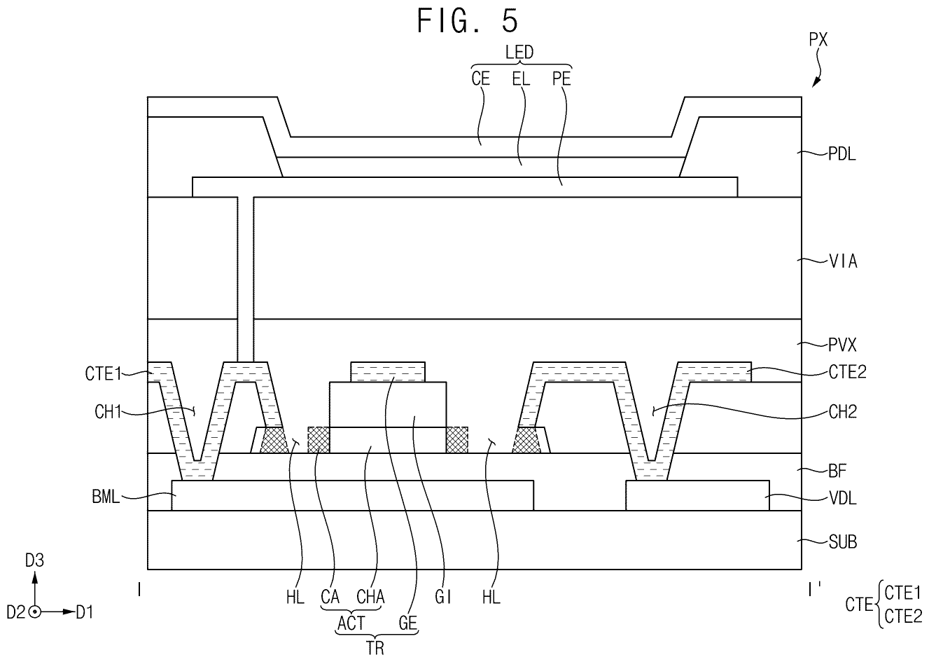

The light-emitting diode LED may include a pixel electrode (e.g., a pixel electrode PE in FIG. 5), a light-emitting layer (e.g., a light-emitting layer EL in FIG. 5), and a common electrode (e.g., a common electrode CE in FIG. 5). The light-emitting diode LED may transmit information to a user by emitting light.

However, with reference to FIG. 3, the pixel PX has been described as including three transistors and one capacitor, but embodiments of the present disclosure are not limited thereto.

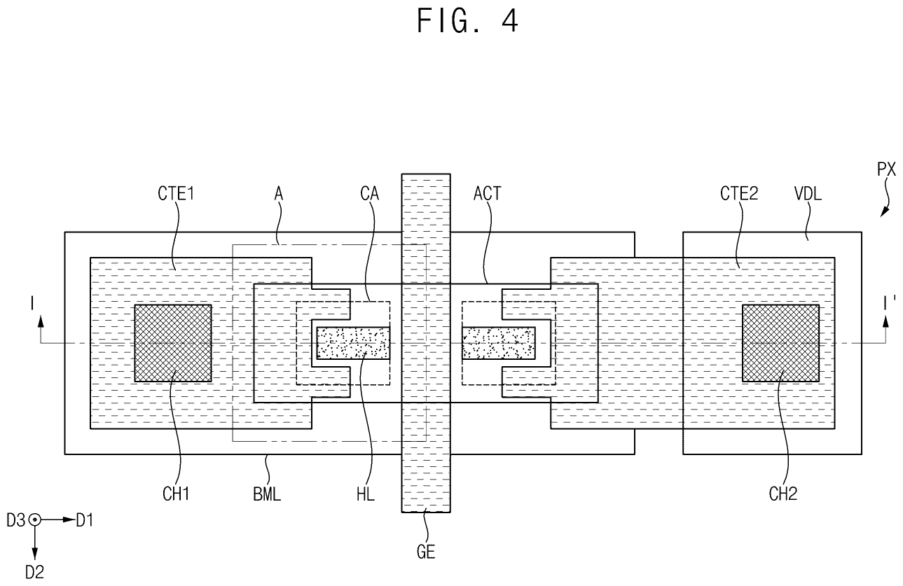

FIG. 4 is a plan view showing an example of a pixel in FIG. 2. FIG. 5 is a cross-sectional view of the pixel taken along the line I-I′ of FIG. 4.

Referring to FIGS. 4 and 5, the pixel PX may include a substrate SUB, a light-blocking portion BML, a driving voltage line VDL, a buffer layer BF, a transistor TR, a gate-insulating layer GI, a contact electrode CTE, an inorganic layer PVX, a via layer VIA, the light-emitting diode LED, and a pixel-defining layer PDL.

The substrate SUB may include a glass substrate, a metal substrate, a plastic substrate, etc. However, embodiments of the present disclosure are not limited thereto, and the substrate SUB may be an inorganic layer, an organic layer, or a composite material layer.

The light-blocking portion BML may be located on the substrate SUB. The light-blocking portion BML may include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), etc. These may be used alone or in combination with each other. For example, the light-blocking portion BML may be a single layer of molybdenum. In addition, the light-blocking portion BML may have a double-layer structure in which a molybdenum layer and a titanium layer are stacked, or a triple-layer structure in which a titanium layer, an aluminum layer, and a titanium layer are stacked.

The driving voltage line VDL may be located on the substrate SUB (as used herein, “located on” or “on” may mean “above”). The driving voltage line VDL may transmit a driving voltage (e.g., ELVDD) to the display panel (e.g., the display panel PNL of FIG. 2). For example, the driving voltage line VDL may include substantially a same material as the light-blocking portion BML. That is, the driving voltage line VDL may be at a same layer as the light-blocking portion BML.

The buffer layer BF may be located on the substrate SUB. For example, the buffer layer BF may be located on the substrate SUB, and may cover the light-blocking portion BML and the driving voltage line VDL. The buffer layer BF may reduce or prevent impurities, such as oxygen and moisture, penetrating into the upper part of the substrate SUB. The buffer layer BF may include an inorganic insulating material. In one or more embodiments, the buffer layer BF may be formed entirely in the display area (e.g., the display area DA in FIG. 1) and the peripheral area (e.g., the peripheral area SA in FIG. 1).

The transistor TR may be located on the buffer layer BF. The transistor TR may include an active layer ACT and a gate electrode GE. The transistor TR may allow current to flow according to a signal from the gate electrode GE.

The active layer ACT may be located on the buffer layer BF. The active layer ACT may include a metal oxide semiconductor, a silicon semiconductor, an organic semiconductor, etc. For example, the oxide semiconductor includes indium (In), gallium (Ga), tin (Sn), zirconium (Zr), vanadium (V), hafnium (Hf), cadmium (Cd), germanium (GE), chromium (Cr), titanium (Ti), zinc (Zn), etc. These may be used alone or in combination with each other. The silicon semiconductor may include amorphous silicon, polycrystalline silicon, etc. The active layer ACT may include a source region, a drain region, and a channel region CHA located between the source region and the drain region.

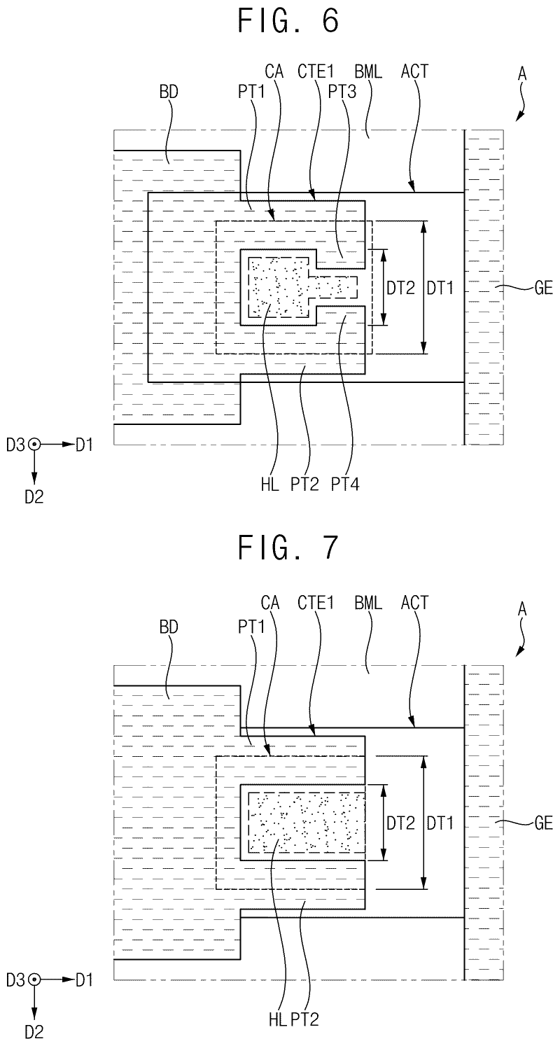

In one or more embodiments, the source region and the drain region may include a conductive area CA, and at least one hole HL may be defined inside the conductive area CA. For example, the conductive area CA may be doped with N-type impurities. Optionally, the conductive area CA may be doped with a P-type impurity. By doping the conductive area CA with N-type impurities or P-type impurities, the active layer ACT may be electrically connected to the contact electrode CTE. The conductive area CA and the hole HL will be described in detail later with reference to FIGS. 6, 7, 8, 9, and 10.

In one or more embodiments, the active layer ACT may include a metal oxide semiconductor. In this case, the active layer ACT may be a semiconductor doped with N-type impurities (e.g., a phosphorus (P), an arsenic (As), etc.) except for the channel region CHA.

The gate-insulating layer GI may be located on the active layer ACT. For example, the gate-insulating layer GI may be located on the buffer layer BF, and may cover the active layer ACT. The gate-insulating layer GI may include an inorganic insulating material. The gate-insulating layer GI may include a structure including a single-layer or multi-layer inorganic insulating material. In one or more embodiments, the gate-insulating layer GI may be formed entirely in the display area (e.g., the display area PA in FIG. 1) and the peripheral area (e.g., the peripheral area SA in FIG. 1).

The gate electrode GE may be located on the gate-insulating layer GI. The gate electrode GE may overlap the channel region CHA of the active layer ACT. Optionally, the gate electrode GE may have a single-layer structure or a multi-layer structure including a plurality of conductive layers. The gate electrode GE may include a conductive material, such as a metal, alloy, conductive metal nitride, conductive metal oxide, transparent conductive material, etc.

The metals that may be used in the gate electrode GE may include gold (Au), silver (Ag), aluminum (AI), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), etc. These may be used alone or in combination with each other.

The alloy that may be used in the gate electrode GE may include an alloy containing aluminum, an alloy containing silver, an alloy containing copper, an alloy containing molybdenum, etc. These may be used alone or in combination with each other.

The conductive metal nitride that may be used in the gate electrode GE may include aluminum nitride (AlN), tungsten nitride (WN), titanium nitride (TiN), chromium nitride (CrN), tantalum nitride (TaN), etc. These may be used alone or in combination with each other.

The conductive metal oxide that may be used in the gate electrode GE may include strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other.

The contact electrode CTE may be located on the gate-insulating layer GI. For example, the contact electrode CTE may be at a same layer as the gate electrode GE. That is, the contact electrode may include a same material as the gate electrode. The contact electrode CTE may be electrically connected to the active layer ACT. In one or more embodiments, the contact electrode CTE may include a first contact electrode CTE1 and a second contact electrode CTE2.

The first contact electrode CTE1 may be electrically connected to the conductive area CA of the active layer ACT and to the light-blocking portion BML. For example, the first contact electrode CTE1 may be connected to the light-blocking portion BML through a first contact hole CH1. For example, the first contact electrode CTE1 may be electrically connected to the active layer ACT. As the light-blocking portion BML is connected to the first contact electrode CTE1, the light-blocking portion BML may have a same voltage as the first contact electrode CTE1. The first contact electrode may include molybdenum (Mo), aluminum (AI), chromium (Cr), gold (Au), titanium (Ti), nickel (Ni), neodymium (Nd), copper (Cu), etc. These may be used alone or in combination with each other. However, embodiments of the present disclosure are not limited thereto.

The second contact electrode CTE2 may be electrically connected to the conductive area CA of the active layer ACT and the driving voltage line VDL. For example, the second contact electrode CTE2 may be connected to the driving voltage line VDL through a second contact hole CH2. For example, the second contact electrode CTE2 may be electrically connected to the active layer ACT. As the driving voltage line VDL is connected to the second contact electrode CTE2, the second contact electrode CTE2 may have a same voltage as the driving voltage line VDL.

The second contact electrode CTE2 may include substantially a same material as the first contact electrode CTE1. That is, the second contact electrode CTE2 may be at a same layer as the first contact electrode CTE1.

The inorganic layer PVX may be located on the gate-insulating layer GI. For example, the inorganic layer PVX may be located on the gate-insulating layer GI, and may cover the gate electrode GE and the contact electrode CTE. The inorganic layer PVX may include an inorganic material. For example, the inorganic layer PVX may include silicon oxide (SiOₓ), silicon nitride (SiNₓ), silicon oxynitride (SiOₓN_{y}), etc. These may be used alone or in combination with each other. However, embodiments of the present disclosure are not limited thereto.

The via layer VIA may be located on the inorganic layer PVX. The via layer VIA may include a substantially flat upper surface. The via layer VIA may include an organic insulating material. Examples of the organic insulating material may include photoresist, polyacrylic resin, polyimide resin, acrylic resin, etc. These may be used alone or in combination with each other. However, embodiments of the present disclosure are not limited thereto.

The light-emitting diode LED may be located on the via layer VIA. For example, the light-emitting diode LED may include an organic light-emitting diode (OLED), an inorganic light-emitting diode, a quantum-dot light-emitting diode (QD-LED), etc. For example, the light-emitting diode LED may include a pixel electrode PE, a light-emitting layer EL, and a common electrode CE.

The pixel electrode PE may be located on the via layer VIA. The pixel electrode PE may be electrically connected to the first contact electrode CTE1 through a contact hole. The pixel electrode PE may transmit an electrical signal to the light-emitting layer EL. The pixel electrode PE may include metal, alloy, metal nitride, conductive metal oxide, transparent conductive material, etc. These may be used alone or in combination with each other. For example, the pixel electrode PE may be an anode electrode.

In one or more embodiments, the first contact electrode CTE1 may be electrically connected to the light-emitting diode LED. For example, the first contact electrode CTE1 may transmit a signal so that the pixel PX may emit light by electrically connected to the light-emitting diode LED through the pixel electrode PE penetrating the inorganic layer PVX and the via layer VIA.

The light-emitting layer EL may be located on the pixel electrode PE. Each light-emitting layer EL may emit light of at least one color among blue, red, or green. However, the present disclosure is not limited thereto, and the light-emitting layer EL may emit a color that is a combination of blue, red, and green. The light-emitting layer EL may include an organic light-emitting material, quantum dots, etc. However, embodiments of the present disclosure are not limited thereto.

The pixel-defining layer PDL may be located on the pixel electrode PE. For example, the pixel-defining layer PDL may expose at least a portion of the pixel electrode PE. The pixel-defining layer PDL may include an inorganic insulating material or an organic insulating material.

The common electrode CE may be located on the light-emitting layer EL and the pixel-defining layer PDL. The common electrode CE may be located on the front surface of the display area (e.g., the display area DA in FIG. 1). The common electrode CE may transmit a driving voltage (e.g., ELVSS) to the light-emitting layer EL. For example, the common electrode CE may include metal, alloy, metal nitride, conductive metal oxide, transparent conductive material, etc. These may be used alone or in combination with each other. For example, the common electrode CE may be a cathode electrode.

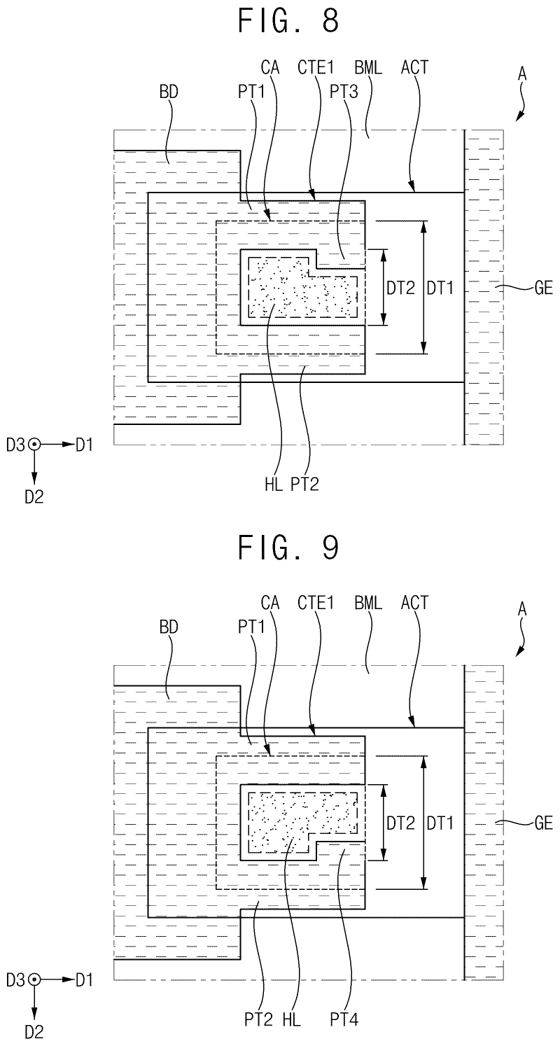

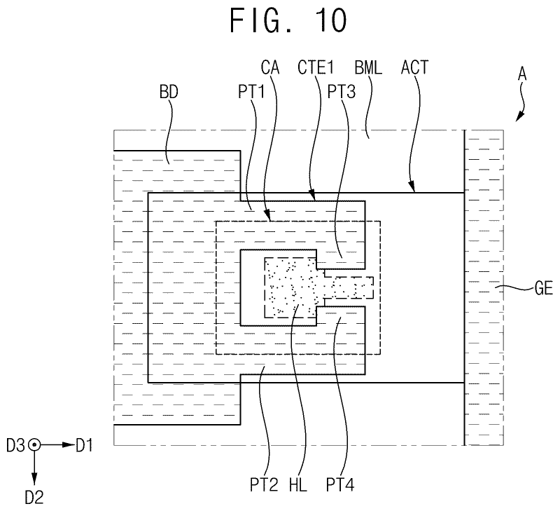

FIG. 6 is a plan view showing an enlarged example of portion A of FIG. 4. FIG. 7 is a plan view showing another enlarged example of portion A of FIG. 4. FIG. 8 is a plan view showing still another enlarged example of portion A of FIG. 4. FIG. 9 is a plan view showing still another enlarged example of portion A of FIG. 4. FIG. 10 is a plan view showing still another enlarged example of portion A of FIG. 4.

Referring to FIGS. 6, 7, 8, 9, and 10, the first contact electrode CTE1 may include a body portion BD and first, second, third, and fourth protrusions PT1, PT2, PT3, and PT4. The first contact electrode CTE1 may be located on the conductive area CA of the active layer ACT and electrically connected to the conductive area CA. In addition, the active layer ACT may include the conductive area CA and the hole HL defined in the conductive area CA. The hole HL may at least partially overlap the light-blocking portion BML in the plan view. For example, the body portion BD may be located on one side of the first contact electrode CTE1.

The first protrusion PT1 may protrude from the body BD in the first direction D1. The first protrusion PT1 may be connected to the body part BD.

The second protrusion PT2 may protrude from the body BD in the first direction D1 and may be spaced apart from the first protrusion PT1 in the second direction D2. The second protrusion PT2 may be connected to the body BD.

The third protrusion PT3 may protrude from the first protrusion PT1 in the second direction D2. The third protrusion PT3 may be connected to the first protrusion PT1 and the body BD.

The fourth protrusion PT4 may protrude from the second protrusion PT2 in a direction opposite to the second direction D2. The fourth protrusion PT4 may be connected to the second protrusion PT2 and the body BD.

As the first contact electrode CTE1 includes the body portion BD and the first, second, third, and fourth protrusions PT1, PT2, PT3, and PT4, the first contact electrode CTE1 may have a shape that surrounds at least a portion of the hole HL. For example, the first contact electrode may have a U-shape or a hook shape in the plan view. However, embodiments of the present disclosure are not limited thereto.

In one or more embodiments, the third protrusion PT3 and PT4 may be spaced apart from each other along the second direction D2. That is, the first contact electrode CTE1 may have a shape with one side open in the plan view. As the first contact electrode CTE1 has a shape with one side open, current may pass through the active layer ACT through the open shape.

In one or more embodiments, the conductive area CA may have a first length DT1 in the second direction D2, and the first protrusion PT1 and the second protrusion PT2 may be spaced apart by a second length DT2 along the direction D2. In one or more embodiments, the first length DT1 may be longer than the second length DT2. Accordingly, as shown in FIG. 10, even if the first contact electrode CTE1 is located along the first direction D1 and/or the second direction D2 shifted, the first contact electrode CTE1 and the conductive area CA may at least partially overlap in the plan view.

In one or more embodiments, at least a portion of each of the body portion BD, the first protrusion PT1, the second protrusion PT2, the third protrusion PT3, and the fourth protrusion PT4 may overlap the conductive area CA in the plan view.

In one or more embodiments, at least a portion of each of the body portion BD, the first protrusion PT1, and the second protrusion PT2 may overlap the conductive area CA in the plan view, and the third protrusion PT3 and the fourth protrusion PT4 may not overlap the conductive area CA in the plan view.

In one or more embodiments, at least a portion of each of the body portion BD, the third protrusion PT3, and the fourth protrusion PT4 may overlap the conductive area CA in the plan view, and the first protrusion PT1 and the second protrusion PT2 may not overlap the conductive area CA in the plan view.

In one or more embodiments, at least a portion of each of the third protrusion PT3 and the fourth protrusion PT4 may overlap the conductive area CA in the plan view, and the body portion BD, the first protrusion PT1, and the second protrusion PT2 may not overlap the conductive area CA in the plan view.

In one or more embodiments, as shown in FIG. 7, the hole HL may have a square or rectangular shape in the plan view. Alternatively, as shown in FIGS. 6, 8, and 9, the hole HL may have a rectangular shape with one side protruding in the plan view. However, embodiments of the present disclosure are not limited thereto. Because the shape of the hole HL may be defined according to a shape of the first contact electrode CTE1, the hole HL may have various shapes, such as circular, trapezoid, or diamond.

The second contact electrode CTE2 may also have substantially a same planar shape as the first contact electrode CTE1. That is, the second contact electrode CTE2 may have a shape that surrounds at least a portion of the hole HL in the plan view.

In this way, because the body portion BD and the first, second, third, and fourth protrusions PT1, PT2, PT3, and PT4 are connected to each other, the electrical signal of the active layer ACT may be transmitted to the first contact electrode CTE1 even when the conductive area CA overlaps only a portion of the plane. As a result, as shown in FIG. 10, the first contact electrode CTE1 may be electrically connected to the active layer ACT even when the first contact electrode CTE1 is shifted in the first direction D1 and/or the second direction D2.

That is, as the first contact electrode CTE1 includes the body BD and the first, second, third, and fourth protrusions PT1, PT2, PT3, and PT4, and has a U-shape or hook shape in the plan view, the first contact electrode CTE1 may exchange an electrical signal with the conductive area CA of the active layer ACT even if the first contact electrode CTE1 is shifted in the first direction D1 and/or the second direction D2. Accordingly, reliability of the display device DD may be improved.

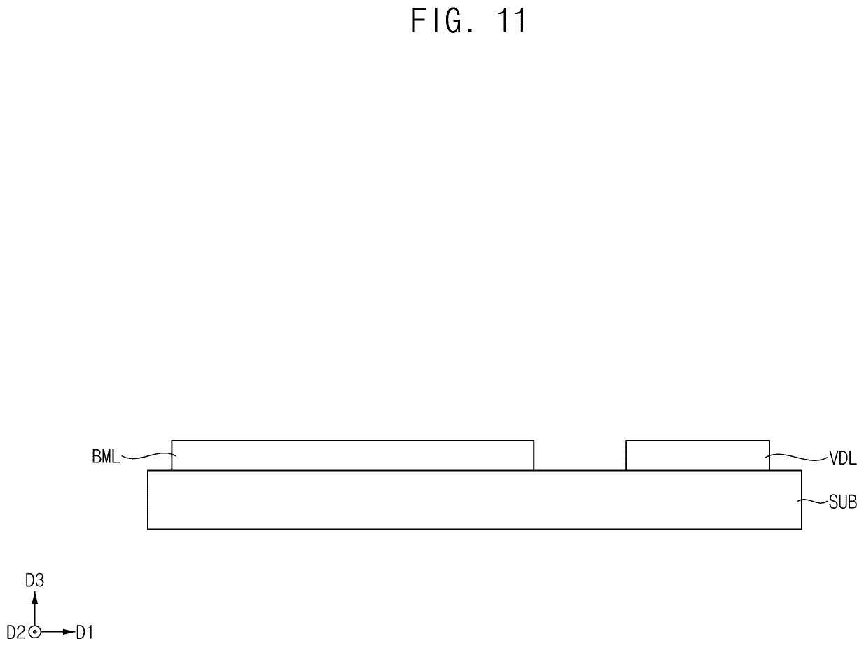

FIGS. 11, 12, 13, 14, 15, 16, and 17 are cross-sectional views showing a method of manufacturing the pixel of FIG. 5.

Referring to FIG. 11, the light-blocking portion BML and the driving voltage line VDL may be formed on the substrate SUB.

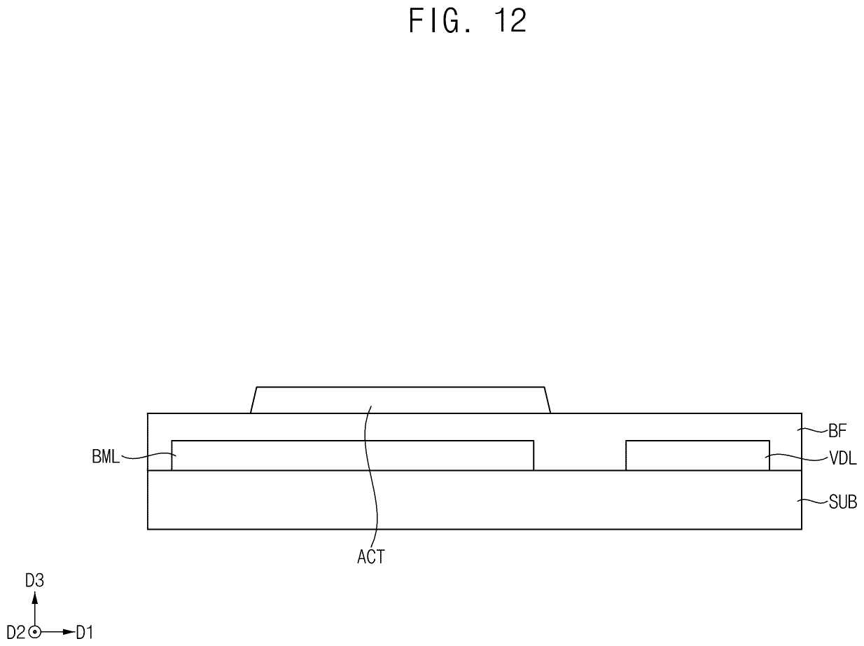

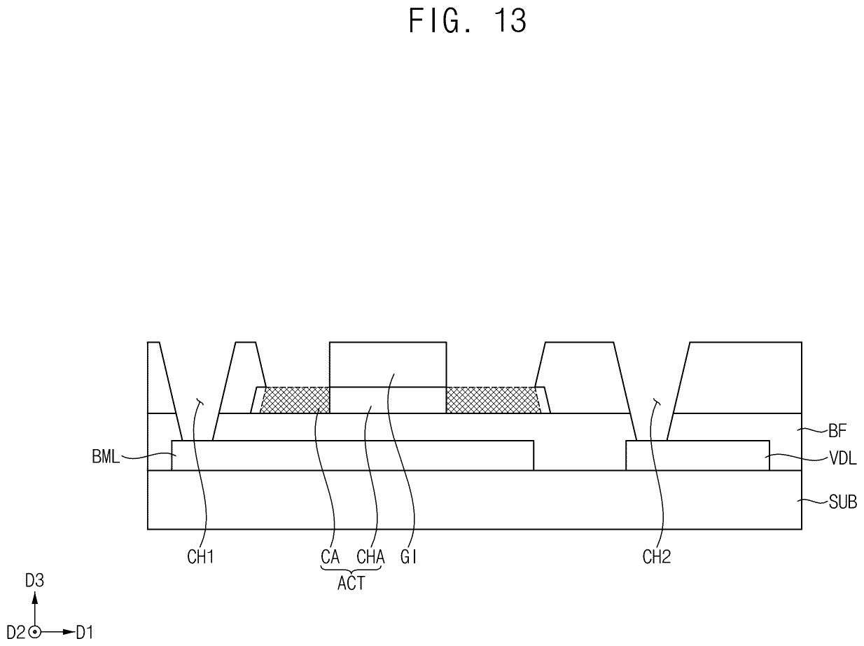

Referring to FIG. 12, the buffer layer BF may be formed on the light-blocking portion BML and the driving voltage line VDL. For example, the buffer layer BF may be formed on the substrate SUB, and may cover the light-blocking portion BML and the driving voltage line VDL.

The active layer ACT may be formed on the buffer layer BF. The active layer ACT may include an oxide semiconductor, a silicon semiconductor, an organic semiconductor, etc.

Referring to FIG. 13, the gate-insulating layer GI may be formed on the active layer ACT. At least a portion of the gate-insulating layer GI may be penetrated through an exposure process. For example, the gate-insulating layer GI may form a first contact hole CH1 and a second contact hole CH2 through the exposure process. Accordingly, at least a portion of each of the light-blocking portion BML and the driving voltage line VDL may be exposed. In addition, after the exposure process, a portion of the active layer ACT may be doped with N-type impurities. In this case, the active layer ACT may include a channel region CHA that is not doped with impurities, and a conductive area CA that is doped with impurities.

For example, the first contact hole CH1 may be formed through the exposure process, and the first contact hole CH1 may expose an upper surface of the light-blocking portion BML. Likewise, the second contact hole CH2 may be formed through the exposure process, and the second contact hole CH2 may expose the upper surface of the driving voltage line VDL.

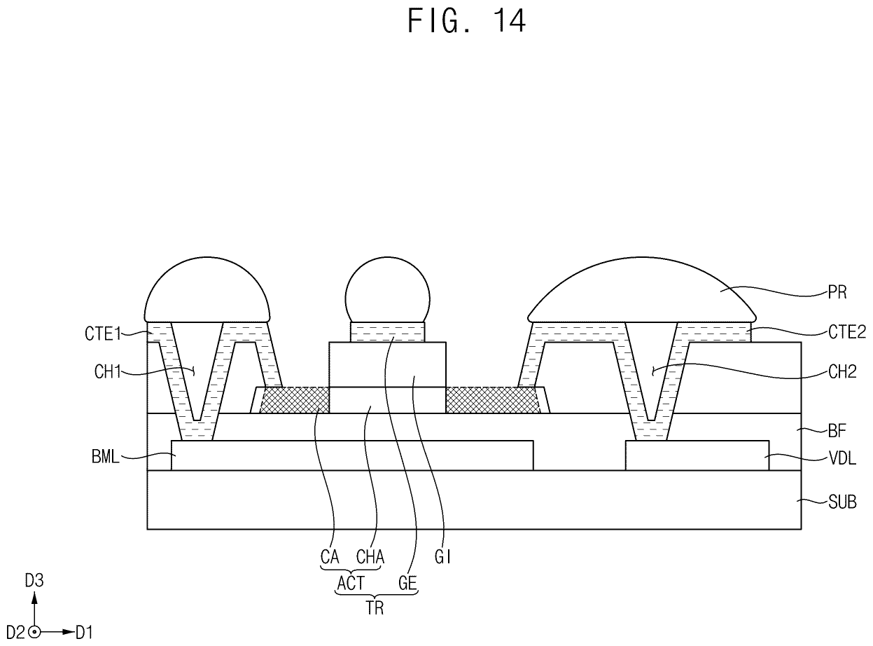

Referring to FIG. 14, the gate electrode GE, the first contact electrode CTE1, and the second contact electrode CTE2 may be formed on the gate-insulating layer GI.

For example, the gate electrode GE may overlap at least a portion of the channel area CHA of the active layer ACT. The first contact electrode CTE1 may be formed on the gate-insulating layer GI along the first contact hole CH1. The first contact electrode CTE1 may be electrically connected to the light-blocking portion BML and the conductive area CA of the active layer ACT.

The second contact electrode CTE2 may be formed on the gate-insulating layer GI along the second contact hole CH2. The second contact electrode CTE2 may be electrically connected to the driving voltage line VDL and the conductive area CA of the active layer ACT.

A conductive layer may be formed on the gate-insulating layer GI. Photoresist PR may be formed on the conductive layer. Through the exposure process, a portion of the conductive layer may be removed using the photoresist PR as a mask. Accordingly, the gate electrode GE, the first contact electrode CTE1, and the second contact electrode CTE2 may be formed on the gate-insulating layer GI.

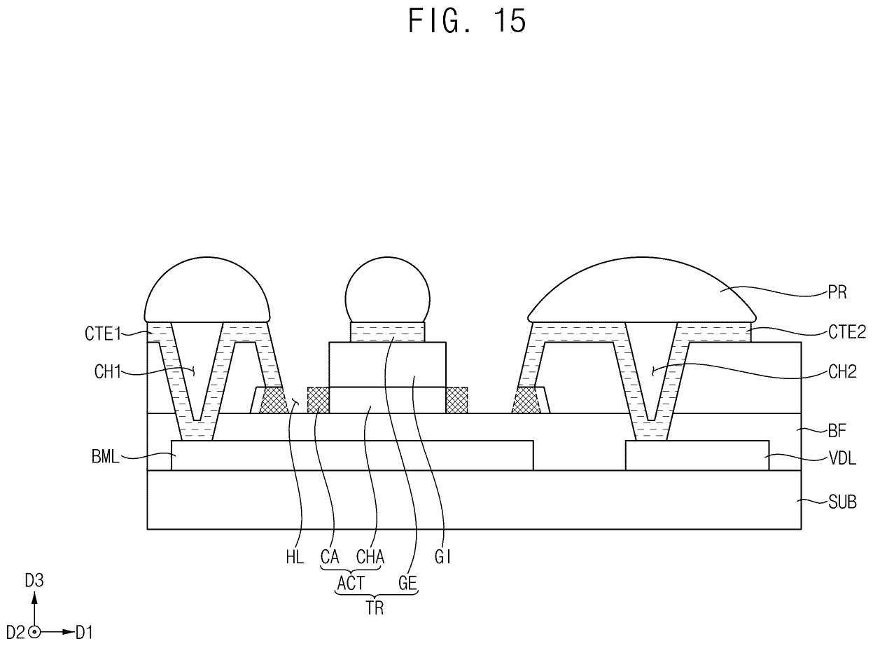

Referring to FIG. 15, an etching process may be performed on areas where the photoresist PR is not formed. Through the etching process, a portion of the conductive area CA of the active layer ACT may be removed to form the hole HL.

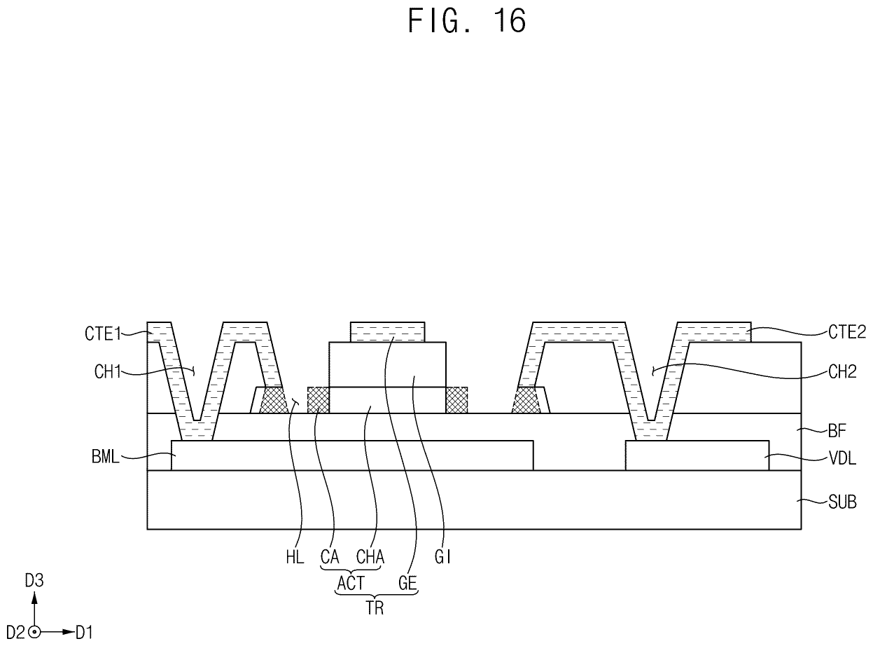

Referring to FIG. 16, after the etching process is performed, the photoresist PR may be removed.

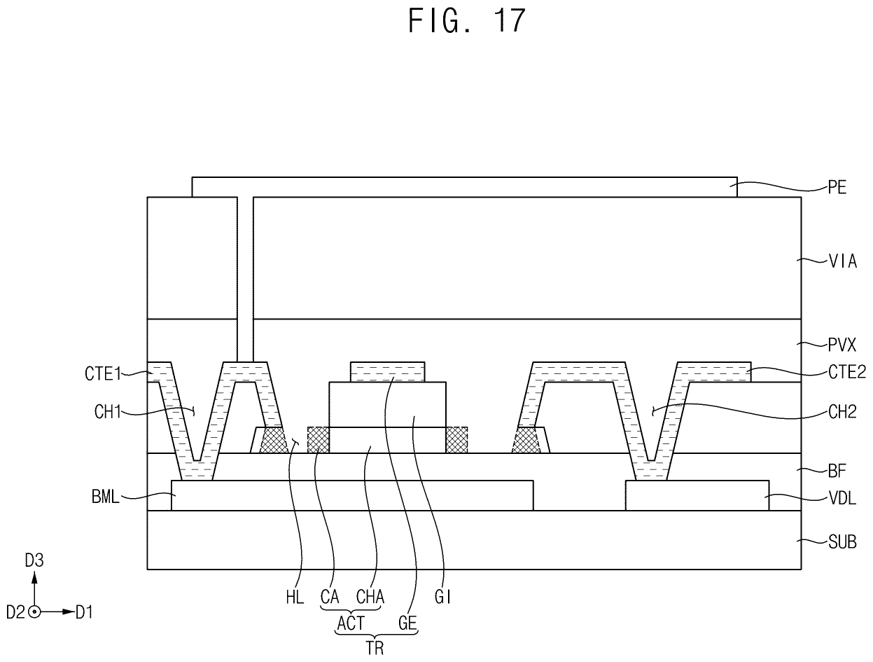

Referring to FIG. 17, the inorganic layer PVX, the via layer VIA, the pixel-defining layer PDL, and the pixel electrode PE may be formed sequentially.

Referring again to FIG. 5, the light-emitting layer EL and the common electrode CE may be sequentially formed on the pixel electrode PE. Accordingly, the pixel PX shown in FIG. 5 may be manufactured.

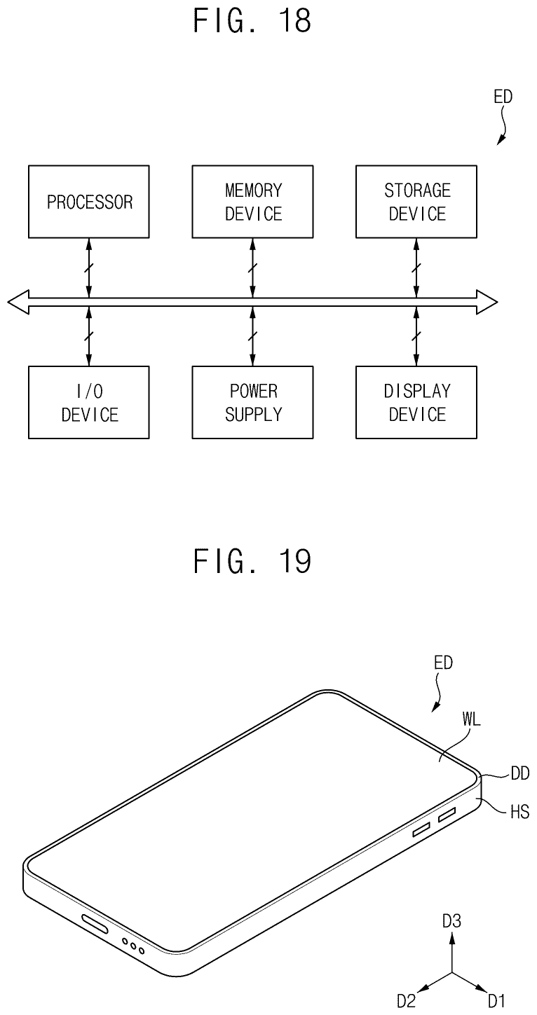

FIG. 18 is a block diagram showing an embodiment of an electronic device. FIG. 19 is a perspective view showing an embodiment of the electronic device.

Referring to FIGS. 18 and 19, an electronic device ED may include a processor, a memory device, a storage device, an input/output device, a power supply, and a display device. The display device included in the electronic device ED may be the display device DD of FIG. 1. In addition, the electronic device ED may further include several ports capable of communicating with a video card, a sound card, a memory card, a USB device, etc., or communicating with other systems.

The processor may perform specific calculations or tasks. In an embodiment, the processor may be a microprocessor, a central processing unit, an application processor, etc. The processor may be connected to other components through an address bus, a control bus, a data bus, etc. In an embodiment, the processor may also be connected to an expansion bus, such as a Peripheral Component Interconnect (PCI) bus. The processor may output data control signals and image data to the timing controller.

The memory device may store data necessary for an operation of the electronic device ED. For example, the memory device may include nonvolatile memory devices such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM), a ferroelectric random access memory (FRAM) device, and/or a volatile memory device such as a dynamic random access memory (DRAM) device, a static random access memory (SRAM) device, a mobile DRAM device, and the like.

The storage device may include a solid state drive (SSD), a hard disk drive (HDD), a CD-ROM, etc. The input/output device may include an input means such as a keyboard, a keypad, a touchpad, a touchscreen, a mouse, etc., and an output means such as a speaker, a printer, etc. In an embodiment, the display device may be included in the input/output device. The power supply may supply power required for the operation of the electronic device ED. The display device may be connected to other components through the buses or other communication links.

In an embodiment, as illustrated in FIG. 19, the electronic device ED may be implemented as a smartphone. The electronic device ED may include a window layer WL, a display device DD, and a housing HS.

The window layer WL may cover the display device DD. For example, the window layer WL may be disposed on the display area (e.g., a display area DA of FIG. 1) of the display device DD to cover the display device DD. Accordingly, the window layer WL may protect the display area of the display device DD where the image is displayed.

The housing HS may surround the display device DD. For example, the display device DD may be accommodated in the housing HS. The housing HS may cover side and bottom of the display device DD. Accordingly, the housing HS may supplement a rigidity of the display device DD and protect the display device DD from external impact.

A functional module such as a camera module or a sensor module may be accommodated in the housing HS. Accordingly, the functional module may be electrically connected to the display device DD and perform a specific function. However, type or arrangement of the functional module according to the embodiments of the present disclosure is not necessarily limited thereto.

However, this is exemplary, and the electronic device ED according to the embodiments of the present disclosure is not necessarily limited thereto. For example, the electronic device ED may be implemented as a mobile phone, a video phone, a smart pad, a smart watch, a tablet PC, a vehicle display, a computer monitor, a notebook computer, a head-mounted display device, etc. In addition, the electronic device ED may be a television, a monitor, a notebook computer, or a tablet. In addition, the electronic device ED may be a car.

The present disclosure may be applied to the display device and the electronic device including a same. For example, the present disclosure may be applied to high-resolution smartphones, mobile phones, smart pads, smart watches, tablet PCs, vehicle navigation systems, televisions, computer monitors, laptops, etc.

While the disclosure has been particularly shown and described with reference to embodiments thereof, it will be understood by those of ordinary skill in the art that various changes in form and details may be made therein without departing from the spirit or scope of the disclosure as defined by the following claims, with functional equivalents thereof to be included therein.

What is claimed is:

1. A display device comprising:
an active layer above a substrate, comprising a conductive area, and defining at least one hole;
a contact electrode electrically connected to the conductive area, and having a shape that surrounds at least a portion of the hole in a plan view; and
a light-emitting diode above the contact electrode, and electrically connected to the contact electrode.

2. The display device of claim 1, wherein the contact electrode has a shape with one side open in plan view.

3. The display device of claim 1, wherein the contact electrode comprises:
a body portion;
a first protrusion protruding from the body portion in a first direction; and
a second protrusion protruding from the body portion in the first direction, and spaced apart from the first protrusion in a second direction crossing the first direction.

4. The display device of claim 3, wherein a portion of the body portion, a portion of the first protrusion, and a portion of the second protrusion overlap the conductive area in plan view.

5. The display device of claim 3, wherein the contact electrode further comprises a third protrusion protruding from the first protrusion in the second direction.

6. The display device of claim 5, wherein at least a portion of the third protrusion overlaps the conductive area in plan view.

7. The display device of claim 3, wherein the contact electrode further comprises a fourth protrusion protruding from the second protrusion in a direction opposite to the second direction.

8. The display device of claim 7, wherein at least a portion of the fourth protrusion overlaps the conductive area in plan view.

9. The display device of claim 3, wherein a first length of the conductive area in the second direction is longer than a second length in which the first protrusion and the second protrusion are spaced apart along the second direction.

10. The display device of claim 1, wherein the conductive area is doped with an N-type impurity.

11. The display device of claim 1, wherein the active layer comprises a metal oxide semiconductor.

12. The display device of claim 1, wherein the hole has a rectangular shape in plan view.

13. The display device of claim 1, wherein the hole has a shape of a rectangle with one side protruding in plan view.

14. The display device of claim 1, further comprising a light-blocking portion above the substrate, and having a portion overlapping the hole in plan view.

15. A display device comprising:
a transistor comprising an active layer above a substrate, comprising a conductive area, and defining at least one hole, and a gate electrode above the active layer overlapping a portion of the active layer;
a contact electrode at a same layer as the gate electrode, electrically connected to the conductive area, and having a shape that surrounds at least a portion of the hole in a plan view; and
a light-emitting diode above the contact electrode, and electrically connected to the contact electrode.

16. The display device of claim 15, wherein the contact electrode has a shape with one side open in plan view.

17. The display device of claim 15, wherein the contact electrode comprises:
a body portion;
a first protrusion protruding from the body portion in a first direction; and
a second protrusion protruding from the body portion in the first direction, and spaced apart from the first protrusion in a second direction crossing the first direction.

18. The display device of claim 17, wherein a portion of the body portion, a portion of the first protrusion, and a portion of the second protrusion overlap the conductive area in plan view.

19. The display device of claim 17, wherein the contact electrode further comprises a third protrusion protruding from the first protrusion in the second direction.

20. The display device of claim 17, wherein the contact electrode further comprises a fourth protrusion protruding in a direction opposite to the second direction from the second protrusion.

21. An electronic device comprising:
a housing; and
a display device stored in the housing and that displays images,
wherein the display device includes:
an active layer above a substrate, comprising a conductive area, and defining at least one hole;
a contact electrode electrically connected to the conductive area, and having a shape that surrounds at least a portion of the hole in a plan view; and
a light-emitting diode above the contact electrode, and electrically connected to the contact electrode.
